(19) United States
(12) Patent Application Publication
(10) Pub. No.: US 2007/0105324 A1
(43) Pub. Date: May 10, 2007

(54) REMOVING SILICON NANO-CRYSTALS

(76) Inventor: Justin K. Brask, Portland, OR (US)

Correspondence Address: INTEL/BLAKELY, 12400 WILSHIRE BOULEVARD, SEVENTH FLOOR, LOS ANGELES, CA, 90025-1030, US

(21) Appl. No.: 11/620,484

(22) Filed: Jan. 5, 2007

Related U.S. Application Data
(62) Division of application No. 11/096,614, filed on Mar. 31, 2005.
Application No. 11/096,614 is a division of application No. 10/397,924, filed on Mar. 25, 2003.

(51) Int. Cl. H01L 21/336

(52) U.S. Cl. 438/297

(57) ABSTRACT

A technique for reducing the number of silicon (Si) nano-crystals available to attach or otherwise deposit upon semiconductor device surfaces. More particularly, embodiments of the invention make a wafer substantially free of Si nano-crystals resulting from a wet etch of oxide layer portions, while not impairing semiconductor device dimensions or electrical characteristics.

### CROSS-REFERENCE TO RELATED APPLICATIONS

This application is a divisional of pending U.S. patent application Ser. No. 11/096,614, filed on Mar. 31, 2005, which is a divisional of U.S. patent application Ser. No. 10/397,924, also pending.

### FIELD

Embodiments of the invention relate to semiconductor manufacturing. More particularly, embodiments of the invention relate to the removal of etching residue, such as silicon particles (Si nano-crystals), from a wafer that has been wet etched during processing.

### BACKGROUND

Creation of semiconductor devices, such as optical, or micro-electronic machines (“MEM”), devices typically require a wet etch operation in order to remove various layers from the wafer. Unfortunately, wet etches can result in a residue of etched material being left on the wafer after the wafer is removed from the wet etch bath. One type of residue that may be produced during a wet etch is silicon residue from. an etched oxide layer, which may take the form of Si nano-crystals. These Si nano-crystals can adversely affect the etched device structure by clinging to the wafer upon the removal of the wafer from the etch bath. thereby altering the intended device feature dimensions.

FIG. 1 illustrates a cross-section of a wafer that has been exposed to a prior art wet etch operation in which Si nano-crystals are produced that can later adhere to the surface of the wafer, In the prior art example of FIG. 1, device gate stacks, consisting of a polysilicon gate 101, oxide layer in which Si nano-crystals are embedded 105, and a Si substrate 110, are formed by wet etching the oxide layer, which contains Si nano-crystals. The wet etch operation releases the Si nano-crystals, which can adhere to the wafer after the wafer is removed from the etch bath, resulting in undesirable device characteristics and low die-per-wafer yield.

### BRIEF DESCRIPTION OF THE DRAWINGS

Embodiments of the invention are illustrated by way of example and not limitation in the figures of the accompanying drawings, in which like references indicate similar elements and in which:

FIG. 1 is a prior art wet etch operation.

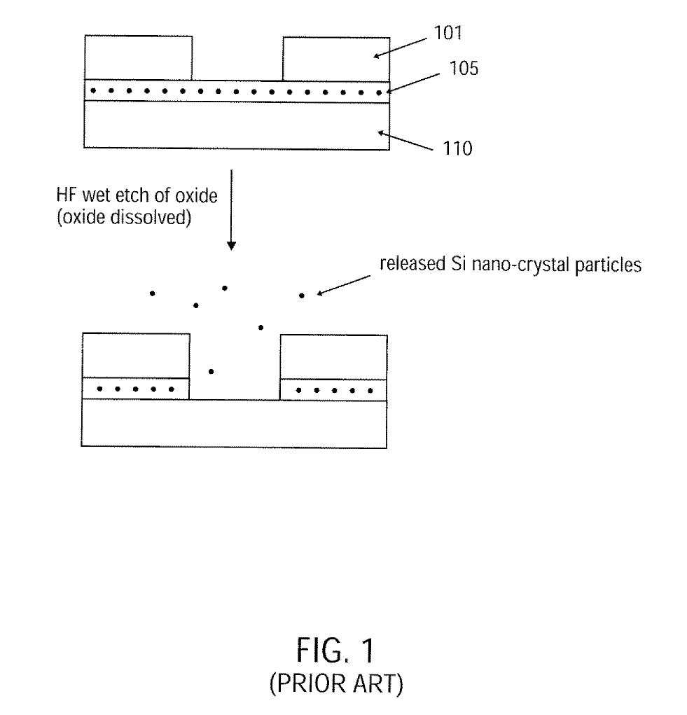

FIG. 2 illustrates a semiconductor processing operation according to one embodiment of the invention in which residue released from a wet etch is dissolved before being able to deposit or attach to the wafer.

FIG. 3 is a flow diagram illustrating a number of processing operations that may be used according to one embodiment of the invention.

### DETAILED DESCRIPTION

Embodiments of the invention described herein relate to complementary metal-oxide-semiconductor (“CMOS”) processing. More particularly, embodiments of the invention relate to the reduction of silicon (“Si”) particles released during a wet etch of an oxide layer of a CMOS device, while not impairing semiconductor device dimensions or electrical characteristics.

Reduction in Si particles, such as Si nano-crystals, released during a wet etch of materials, such as unwanted portions of an oxide layer, can be achieved by including in the wet etch bath solution an oxidant, such as HNO₃ (nitric acid) or H₂O₂ (hydrogen peroxide), aqueous solutions of HNO₃, O₃ (ozone), O₂, H₂O₂, or organic peroxide. Particularly, oxidants introduced into a wet etch bath can combine with Si nano-crystals in order to for silicon dioxide (SiO₂), which is soluble in the wet etch bath and therefore helps prevent Si nano-crystals from being deposited or adhering to device features, such as the oxide, gate polysilicon, or the substrate exposed by the etch. The wafer can then be removed from the wet etch substantially free of Si nano-particles on important device feature surfaces.

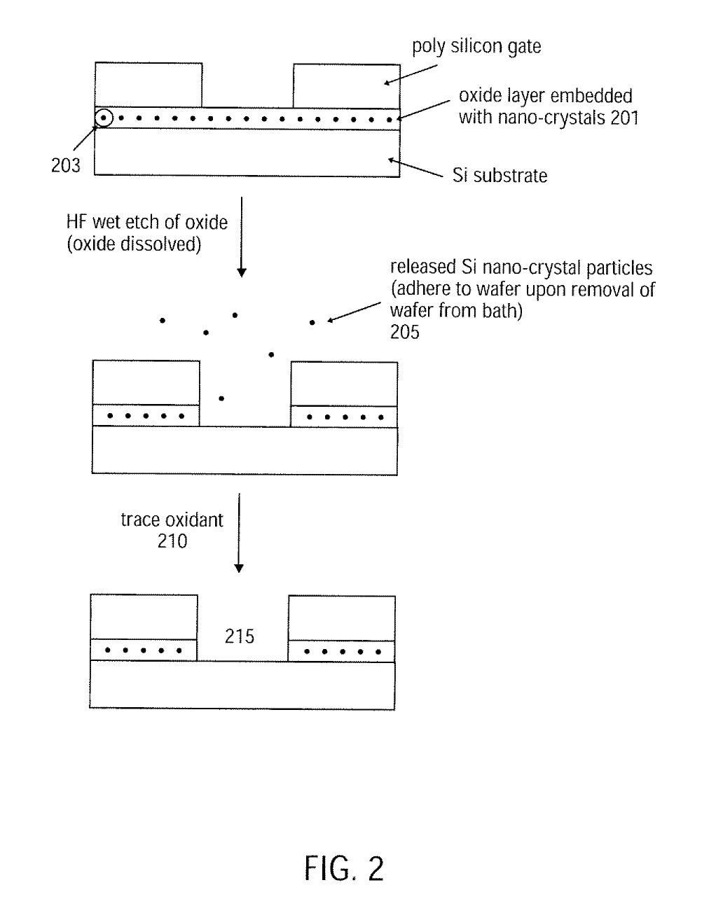

FIG. 2 illustrates a wafer on which a wet etch is performed according to one embodiment of the invention. The oxide 201 contains Si nano-crystals 203 that are released 205 into the wet etch bath during the etch of the oxide. The introduction of an oxidant 2 10, such as HNO₃ or H₂O₂, aqueous solutions of HNO₃, O₃, O₂, H₂O₂, or organic peroxide, however, can help reduce the number of Si nano-crystals in the wet etch bath that may attach or otherwise deposit on important device feature surfaces after the wafer is removed from the wet etch bath. In the embodiment illustrated in FIG. 2, the combination of the oxidant and the Si nano-crystals yields silicon dioxide (SiO₂) [[213]], which is soluble in the wet etch bath, thereby making the wafer 215 substantially free of Si nano-crystals.

Embodiments of the invention can be incorporated into various semiconductor process operations, including those involved in wet etching of portions of an oxide layer, as illustrated in FIG. 2. Other embodiments of the invention may be used in other semiconductor process operations. such as wet etching of other semiconductor device materials. Furthermore, other embodiments may use varying oxidants, etching agents, or combinations thereof.

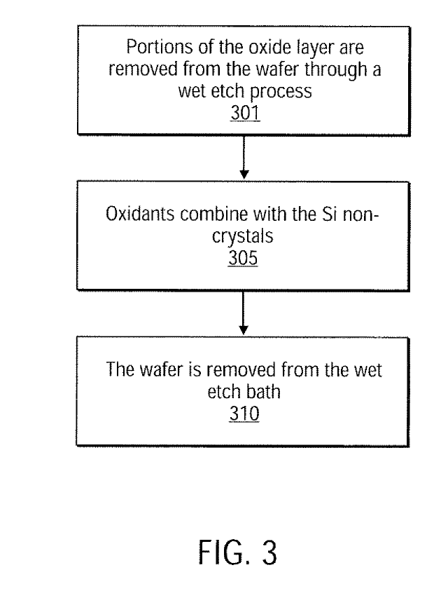

FIG. 3 Is a flow diagram illustrating a number of semiconductor process operations in which one embodiment of the invention may be used. Portions of the oxide layer are removed from the wafer through a wet etch process at operation 301, in which the wet etch bath contains oxidants to combine with any Si nano-crystals released as a result of the etch. Once the Si nano-crystals are released into the wet etch bath, the oxidants combine with the Si nano-crystals at operation 305 to produce a compound, SiO₂, which is soluble in the wet etch bath. After the wafer is removed from the wet etch bath at operation 310, the exposed silicon substrate, polysilicon gate structure, and other device material surfaces are substantially free of Si nano-crystals that may change the electrical characteristics and/or dimensions of the semiconductor device.

Although the invention has been described with reference to illustrative embodiments, this description is not intended to be construed in a limiting sense. Various modifications of the illustrative embodiments, as well as other embodiments, which are apparent to persons skilled in the art to which the invention pertains are deemed to lie within the spirit and scope of the invention.

What is claimed is:

1. An apparatus comprising:
first means for removing a portion of an oxide layer;
second means for dissolving silicon (Si) particles released as a result of removing the portion of the oxide layer.

2. The apparatus of claim 1 wherein the first means is a wet etch bath.

3. The apparatus of claim 1 wherein the second means is an oxidant chosen from a group consisting of HNO₃, H₂O₂, aqueous solutions of HNO₃, O₃, O₂, H₂O₂, and organic peroxide.

4. The apparatus of claim 1 wherein the first means is a wet etch bath containing an oxidant chosen from a group consisting of HNO₃, H₂O₂, aqueous solutions of HNO₃, O₃, O₂, H₂O₂, and organic peroxide.

5. The apparatus of claim 4 wherein the second means is a chemical reaction between the oxidant and the Si particles to form SiO₂.

6. The apparatus of claim 1 further comprising a third means to form a polysilicon gate on a portion the oxide layer not to be removed by the first means.
